(19) United States
(12) Patent Application Publication
(10) Pub. No.: US 2020/0083488 A1
(43) Pub. Date: Mar. 12, 2020

(54) MANUFACTURING METHOD OF OLED DISPLAY AND OLED DISPLAY

(71) Applicant: Shenzhen China Star Optoelectronics Semiconductor Display Technology Co., Ltd., Shenzhen, Guangdong (CN)

(72) Inventor: Xiaoxing ZHANG, Shenzhen, Guangdong (CN)

(73) Assignee: Shenzhen China Star Optoelectronics Semiconductor Display Technology Co., Ltd., Shenzhen (CN)

(21) Appl. No.: 15/743,969

(22) PCT Filed: Nov. 20, 2017
(86) PCT No.: PCT/CN2017/111967

§ 371 Date: Jan. 11, 2018

(30) Foreign Application Priority Data
Sep. 28, 2017 (CN) 201710901860.6

(51) Int. Cl. H01L 51/56; H01L 51/00; H01L 51/52

(52) U.S. Cl. CPC H01L 51/56; H01L 51/0004; H01L 2251/305; H01L 51/5221; H01L 51/0022

(57) ABSTRACT

The present disclosure provides a manufacturing method of an OLED display and an OLED display. Before preparing the OLED light emitting layer of the manufacturing method, respectively printing the liquid conductive material in the plurality of pixel areas of the TFT substrate and drying to remove the solvent, thereby obtaining a flat conductive layer. Together serving the conductive layer and the pixel electrode on the TFT substrate as an anode structure, and then printing the liquid OLED luminous material on each of the plurality of pixel areas of the TFT substrate and drying to form an OLED light emitting layer on the conductive layer. Due to the flat surface of the conductive layer, the thickness of the OLED light emitting layer obtained by printing on the conductive layer is uniform, so that the obtained OLED display emits light evenly, which effectively improves the display effect of the OLED display.

### RELATED APPLICATIONS

The present application is a National Phase of International Application Number PCT/CN2017/111967, filed on Nov. 20, 2017, and claims the priority of China Application 201710901860.6, filed on Sep. 28, 2017.

### FIELD OF THE DISCLOSURE

The present disclosure relates to a display technology field, and more particularly to a manufacturing method of an OLED display and an OLED display.

### BACKGROUND OF THE DISCLOSURE

Organic Light Emitting Display (OLED) has the advantages of self-luminous, low driving voltage, high luminous efficiency, short response time, sharpness and contrast, nearly 180° viewing angle, wide temperature range, flexible display and large-area full-color display. It is recognized as the most promising display device in the industry.

According to the driving mode, the OLEDs can be divided into two types: a passive matrix OLED (PMOLED) and an active matrix OLED (AMOLED), namely direct addressing and thin film transistor (TFT) matrix addressing two categories. Wherein, AMOLED has a matrix arrangement of pixels, belonging to the active display type, high luminous efficiency, usually used for high-definition large-size display device.

The OLED device generally includes a substrate, an anode arranged on the substrate, a hole injection layer arranged on the anode, a hole transport layer arranged on the hole injection layer, a light emitting layer arranged on the hole transport layer, an electron transport layer arranged on the light emitting layer, an electron injection layer arranged on the electron transport layer and a cathode arranged on the electron injection layer. The lighting principle of the OLED device is:

the semiconductor material and the organic light emitting material cause light emission through the carrier injection and recombination driven by the electric field. Specifically, the OLED device usually adopts an indium tin oxide (ITO) electrode and a metal electrode as the anode and the cathode of the device respectively. Under a certain voltage, electrons and holes are injected into the electron transport layer and the hole transport layer from the cathode and the anode, respectively, and the electrons and holes migrate to the light emitting layer through the electron transport layer and the hole transport layer, respectively, and meet in the light emitting layer to form excitons and excite the light emitting molecules that emit visible light through radiation relaxation.

In the prior art, an OLED luminescent material is often deposited on a pixel area of a TFT substrate by vapor deposition to form a luminescent layer of the OLED device. Due to the characteristics of the vapor deposition process, the utilization of the OLED luminescent material is very low, the product cost is difficult to be reduced. At the same time, due to the size and precision of the mask, it is difficult to form the OLED light emitting material by vapor deposition in the large-size and high-resolution OLED display. The technology of making OLED light emitting layer by means of Ink-jet Print is correspondingly born. Specifically, the liquid OLED luminescent material is dropped onto the pixel area of the TFT substrate through a high-precision printer, the OLED luminescent material is dried to form an OLED light emitting layer. The utilization rate of the OLED luminescent materials in this way is high, can reduce product costs. However, since the OLED luminescent material in this manner is initially in a solution state, the flatness of the pixel area is very high after dropping onto the pixel area of the TFT substrate. If the pixel area is not flat, the thickness of the OLED light emitting layer formed by drying the OLED luminescent material is not uniform, resulting in non-uniform light-emitting efficiency and brightness irregularity (Mura).

Please refer to FIG. 1, in the manufacturing process of an existing OLED display, in manufacturing the TFT substrate 100′, forming the planarization layer 120′ by applied the planarizing material on the entire surface of the TFT array layer 110′ before forming the pixel electrode 130′, and forming the pixel electrode 130′ on the planarization layer 120′, then forming the pixel defining layer 200′ on the TFT substrate 100′, arranging the plurality of through holes 210′ exposing the pixel electrode 130′ on the pixel defining layer 200′, respectively defining the plurality of pixel areas 101′ on the TFT substrate 100′ according to the plurality of through holes 210′, dropping the OLED luminescent material in the plurality of pixel area 101′ and drying, and obtaining the OLED light emitting layer 300′ located in the plurality of pixel areas 101′. The planarization layer 120′ is arranged to improve the non-uniform thickness of the OLED light emitting layer 300′ due to the unevenness of the pixel area 101′. However, the improvement of the flatness of the pixel area 101′ by the planarization layer 120′ is very limited due to the circuit traces and opening requirements of the TFT substrate 100′ itself. The problem of uneven brightness caused by the uneven thickness of the OLED light emitting layer 300′ still occurs.

### SUMMARY OF THE DISCLOSURE

An object of the present disclosure is to provide a manufacturing method of an OLED display, which can make the film thickness of the OLED light emitting layer uniform, make the OLED display obtained uniform and improve the display effect of the OLED display.

Another object of the present disclosure is to provide an OLED display which has the uniform thickness of the OLED light emitting layer, uniform light emission during display, and good display effect.

To achieve the above object, the present disclosure firstly provides a manufacturing method of an OLED display, including the following steps:

Step S1, providing a TFT substrate, forming a pixel defining layer on the TFT substrate;

arranging a plurality of through holes on the pixel defining layer; and defining a plurality of pixel areas on the TFT substrate according to the plurality of through holes;

Step S2, respectively printing liquid conductive material in the plurality of pixel areas of the TFT substrate, drying the liquid conductive material, and forming a conductive layer covering the pixel area;

Step S3, respectively printing liquid OLED luminescent material in the plurality of pixel areas in the TFT substrate, drying the liquid OLED luminescent material, and forming an OLED light emitting layer on the conductive layer.

The manufacturing method of an OLED display further including:

Step S4, forming a cathode layer on the pixel defining layer and the OLED light emitting layer, and obtaining an OLED display.

The TFT substrate includes: a TFT array layer, a planarization layer covering on the TFT array layer, and a pixel electrode arranged on the planarization layer.

The plurality of through holes exposes the pixel electrode.

The material of the pixel electrode is transparent metal oxide.

The liquid conductive material is solution-state carbon nano-silver material or solution-state carbon nano-material.

The present disclosure further provides an OLED display includes:

a TFT substrate;

a pixel defining layer arranged on the TFT substrate, a plurality of through holes arranged on the pixel defining layer, a plurality of pixel areas defined on the TFT substrate according to the plurality of through holes;

a conductive layer arranged in the pixel area on the TFT substrate; and

an OLED light emitting layer arranged in the pixel area on the conductive layer;

the conductive layer is prepared by respectively printing liquid conductive material in the plurality of pixel areas of the TFT substrate and drying the liquid conductive material.

The OLED display further includes a cathode layer on the pixel defining layer and the OLED light emitting layer.

The TFT substrate includes: a TFT array layer, a planarization layer covering on the TFT array layer and a pixel electrode arranged on the planarization layer; the plurality of through holes exposes the pixel electrode.

The material of the pixel electrode is transparent metal oxide.

The liquid conductive material is solution-state carbon nano-silver material or solution-state carbon nano-material.

The present disclosure further provides a manufacturing method of an OLED display, including the following steps:

Step S1, providing a TFT substrate, forming a pixel defining layer on the TFT substrate;

arranging a plurality of through holes on the pixel defining layer; and

defining a plurality of pixel areas on the TFT substrate according to the plurality of through holes;

Step S2, respectively printing liquid conductive material in the plurality of pixel areas of the TFT substrate, drying the liquid conductive material, and forming a conductive layer covering the pixel area;

Step S3, respectively printing liquid OLED luminescent material in the plurality of pixel areas in the TFT substrate, drying the liquid OLED luminescent material, and forming an OLED light emitting layer on the conductive layer;

Step S4, forming a cathode layer on the pixel defining layer and the OLED light emitting layer, and obtaining an OLED display.

Wherein the TFT includes: a TFT array layer, a planarization layer covering on the TFT array layer, and a pixel electrode arranged on the planarization layer;

the plurality of through holes exposes the pixel electrode.

Wherein the material of the pixel electrode is transparent metal oxide.

Wherein the liquid conductive material is solution-state carbon nano-silver material or solution-state carbon nano-material.

The beneficial effects of the present disclosure are as follows: before preparing the OLED light emitting layer of the manufacturing method of the OLED display, respectively printing the liquid conductive material in the plurality of pixel areas of the TFT substrate and drying to remove the solvent, thereby obtaining a flat conductive layer. Together serving the conductive layer and the pixel electrode on the TFT substrate as an anode structure, and then printing the liquid OLED luminous material on each of the plurality of pixel areas of the TFT substrate and drying to form an OLED light emitting layer on the conductive layer. Due to the flat surface of the conductive layer, the thickness of the OLED light emitting layer obtained by printing on the conductive layer is uniform, so that the obtained OLED display emits light evenly, which effectively improves the display effect of the OLED display. The OLED display provided by the present disclosure is manufactured by the above method for fabricating an OLED display. The thickness of the OLED light emitting layer is uniform, the light is uniform when displayed, and the display effect is good.

### BRIEF DESCRIPTION OF THE DRAWINGS

For further understanding of the features and technical contents of the present disclosure, reference should be made to the following detailed description and accompanying drawings of the present disclosure. However, the drawings are for reference only and are not intended to limit the present disclosure.

FIG. 1 is a schematic structural diagram of an existing OLED display;

FIG. 2 is a flow chart of the method of making an OLED display of the present disclosure;

FIG. 3 is a schematic diagram of step S1 of the method for fabricating the OLED display of the present disclosure;

FIG. 4 is a schematic diagram of step S2 of the method for fabricating the OLED display of the present disclosure;

FIG. 5 is a schematic diagram of step S3 of the method for fabricating the OLED display of the present disclosure;

FIG. 6 is a schematic diagram of step S4 of the method for fabricating the OLED display of the present disclosure and a schematic structural diagram of the OLED display of the present disclosure.

### DETAILED DESCRIPTION OF PREFERRED EMBODIMENTS

To further illustrate the technical means adopted by the present disclosure and the effects thereof, the following describes the preferred embodiments of the present disclosure and the accompanying drawings in detail.

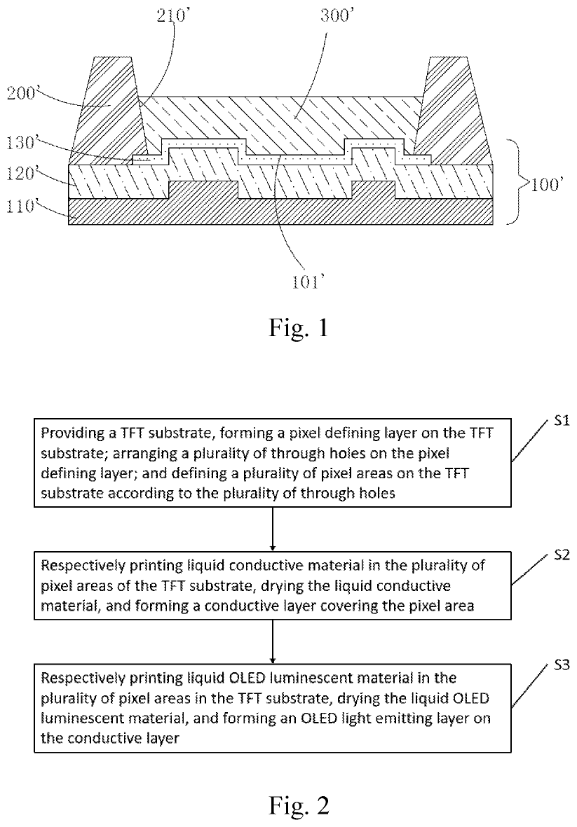

Please refer to FIG. 2, the manufacturing method of an OLED display of the present disclosure provided, including the following steps:

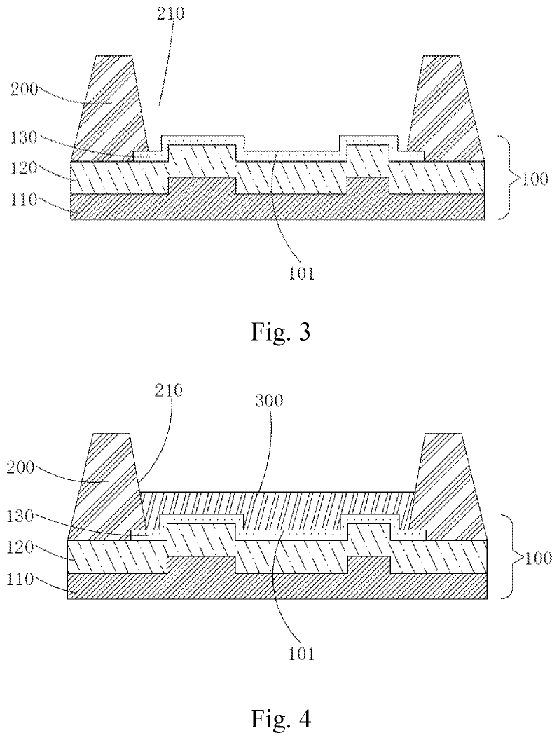

Step S1, referring to FIG. 3, providing a TFT substrate 100, forming a pixel defining layer 200 on the TFT substrate 100;

arranging a plurality of through holes 210 on the pixel defining layer 200; and defining a plurality of pixel areas 101 on the TFT substrate 100 according to the plurality of through holes 210.

Wherein the TFT substrate 100 includes: a TFT array layer 110, a planarization layer 120 covering on the TFT array layer 110, and a pixel electrode 130 arranged on the planarization layer 120;

The plurality of through holes 210 exposes the pixel electrode 130.

Wherein the material of the pixel electrode 130 is transparent metal oxide. Preferably, the material of the pixel electrode 130 is indium tin oxide (ITO).

Step S2, referring to FIG. 4, respectively printing the liquid conductive material in the plurality of pixel areas 101 of the TFT substrate 100, drying the liquid conductive material, removing the solvent of the liquid conductive material, and forming the conductive layer 300 covering the pixel area 101, together forming an anode structure by the conductive layer 300 and the pixel electrode 130 on the TFT substrate 100.

It should be noted that, in step S2, since the conductive layer 300 is formed by printing, the upper surface of the conductive layer 300 can still have higher flatness even if the upper surface of the TFT substrate 100 has uneven protrusions in the pixel area 101.

Specifically, the liquid conductive material is printed in the plurality of pixel regions 101 by using a high-precision printer in step 2.

Specifically, the conductive material in the solution state can be selected as a carbon nano-silver material in a solution state or a carbon nanomaterial solution in a solution state, and other solution materials that have good conductivity after drying can also be selected.

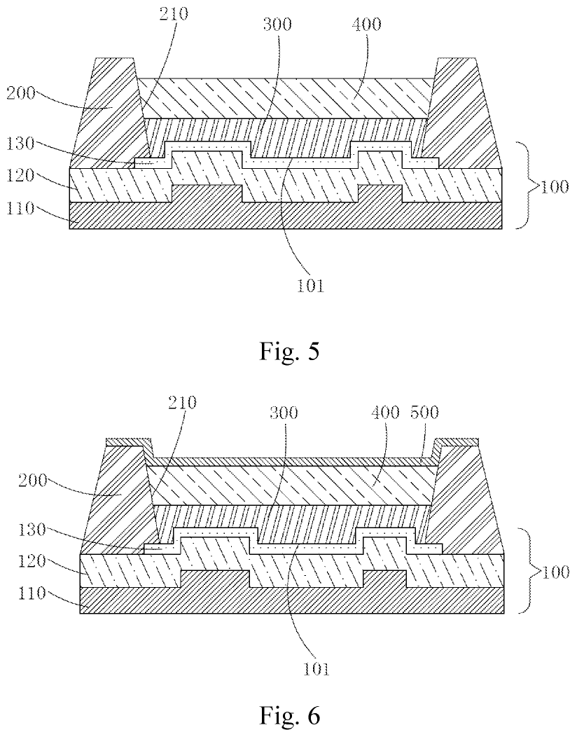

Step S3, referring to FIG. 5, respectively printing the liquid OLED luminescent material in the plurality of pixel areas 101 of the TFT substrate 100, drying the liquid OLED luminescent material, removing the solvent of the liquid OLED luminescent material, and forming the OLED light emitting layer 400 on the conductive layer 300.

Specifically, before forming the OLED light emitting layer 400 in step S3, the method further includes a step of sequentially forming a hole injection layer and a hole transport layer. After forming the OLED light emitting layer 400, a step of sequentially forming an electron transport layer and an electron injection layer may be further included. The hole injection layer, the hole transport layer, the electron transport layer, and the electron injection layer are both prepared by printing.

It should be noted, because the flatness of the upper surface of the conductive layer 300 formed in step S2 is very high, the uniformity of the thickness of the OLED light emitting layer 400 after the OLED light emitting layer 400 is formed on the conductive layer 300 in step S3 by printing is good.

Specifically, a high-precision printer is used to print the liquid OLED light emitting material into the plurality of pixel areas 101 in step S3.

Step S4, referring to FIG. 6, forming the cathode layer 500 on the pixel defining layer 200 and the OLED light emitting layer 400, and obtaining the OLED display. The thickness of the OLED light emitting layer 400 of the OLED display is uniform, so that the OLED display emits uniform light during display and has a good display effect.

Please refer to FIG. 6, based on the same inventive concept, the present disclosure further provides an OLED display made by the above method for fabricating an OLED display, including:

a TFT substrate 100;

a pixel defining layer 200 arranged on the TFT substrate 100, a plurality of through holes 210 arranged on the pixel defining layer 200, a plurality of pixel areas 101 defined on the TFT substrate 100 according to the plurality of through holes 210;

a conductive layer 300 arranged in the pixel area 101 on the TFT substrate 100; and

an OLED light emitting layer 400 arranged in the pixel area 101 on the conductive layer 300;

the conductive layer 300 is prepared by respectively printing liquid conductive material in the plurality of pixel areas 101 of the TFT substrate 100 and drying the liquid conductive material.

Specifically, the OLED display further includes a cathode layer 500 arranged on the pixel defining layer 200 and the OLED light emitting layer 400.

Specifically, the OLED display may further include a hole injection layer and a hole transport layer which are sequentially arranged from bottom to top between the conductive layer 300 and the OLED light emitting layer 400, and an electron transport layer and an electron injection layer which are sequentially arranged from bottom to top between the OLED light emitting layer 400 and the cathode layer 500.

Specifically, the TFT substrate 100 includes a TFT array layer 110, a planarization layer 120 covering the TFT array layer 110, and a pixel electrode 130 arranged on the planarization layer 120. Each of the through holes 210 exposes the pixel electrode 130. The conductive layer 300 and the pixel electrode 130 together form an anode structure.

Specifically, the material of the pixel electrode 130 is transparent metal oxide.

Specifically, the conductive material in the solution state can be selected as a carbon nano-silver material in the solution state or a carbon nanomaterial in the solution state or other solution materials that have good conductivity after drying.

It should be noted, since the conductive layer 300 is formed by printing in the pixel area 101 before the OLED light emitting layer 400 is formed. Even though the upper surface of the TFT substrate 100 has irregular protrusions in the pixel area 101, the conductive layer 300 can have an upper surface with a higher flatness. The thickness of the OLED light emitting layer 400 arranged on the conductive layer 300 is uniform, so that the OLED display emits uniform light during display and has a good display effect.

In summary, before preparing the OLED light emitting layer of the manufacturing method of the OLED display, respectively printing the liquid conductive material in the plurality of pixel areas of the TFT substrate and drying to remove the solvent, thereby obtaining a flat conductive layer. Together serving the conductive layer and the pixel electrode on the TFT substrate as an anode structure, and then printing the liquid OLED luminous material on each of the plurality of pixel areas of the TFT substrate and drying to form an OLED light emitting layer on the conductive layer. Due to the flat surface of the conductive layer, the thickness of the OLED light emitting layer obtained by printing on the conductive layer is uniform, so that the obtained OLED display emits light evenly, which effectively improves the display effect of the OLED display. The OLED display provided by the present disclosure is manufactured by the above method for fabricating an OLED display. The thickness of the OLED light emitting layer is uniform, the light is uniform when displayed, and the display effect is good.

In the foregoing, other various modifications and variations may be made by those skilled in the art according to the technical solutions and technical solutions of the present disclosure, and all such changes and modifications shall fall within the protection scope of the claims of the present disclosure.

What is claimed is:

1. A manufacturing method of an OLED display, comprising the following steps:
Step S1, providing a TFT substrate, forming a pixel defining layer on the TFT substrate;
arranging a plurality of through holes on the pixel defining layer; and defining a plurality of pixel areas on the TFT substrate according to the plurality of through holes;
Step S2, respectively printing liquid conductive material in the plurality of pixel areas of the TFT substrate, drying the liquid conductive material, and forming a conductive layer covering the pixel area;
Step S3, respectively printing liquid OLED luminescent material in the plurality of pixel areas in the TFT substrate, drying the liquid OLED luminescent material, and forming an OLED light emitting layer on the conductive layer.

2. The manufacturing method of an OLED display according to claim 1, further comprising:
Step S4, forming a cathode layer on the pixel defining layer and the OLED light emitting layer, and obtaining an OLED display.

3. The manufacturing method of an OLED display according to claim 1, wherein the TFT substrate comprises: a TFT array layer, a planarization layer covering on the TFT array layer, and a pixel electrode arranged on the planarization layer; and
the plurality of through holes exposes the pixel electrode.

4. The manufacturing method of an OLED display according to claim 3, wherein material of the pixel electrode is transparent metal oxide.

5. The manufacturing method of an OLED display according to claim 1, wherein material of the liquid conductive is solution-state carbon nano-silver material or solution-state carbon nano-material.

6. An OLED display comprises:
a TFT substrate;
a pixel defining layer arranged on the TFT substrate, a plurality of through holes arranged on the pixel defining layer, a plurality of pixel areas defined on the TFT substrate according to the plurality of through holes;
a conductive layer arranged in the pixel area on the TFT substrate; and
an OLED light emitting layer arranged in the pixel area on the conductive layer;
the conductive layer is prepared by respectively printing liquid conductive material in the plurality of pixel areas of the TFT substrate and drying the liquid conductive material.

7. The OLED display according to claim 6, further comprises a cathode layer on the pixel defining layer and the OLED light emitting layer.

8. The OLED display according to claim 6, wherein the TFT substrate comprises: a TFT array layer, a planarization layer covering on the TFT array layer, and a pixel electrode arranged on the planarization layer; the plurality of through holes exposes the pixel electrode.

9. The OLED display according to claim 8, wherein material of the pixel electrode is transparent metal oxide.

10. The OLED display according to claim 6, wherein material of the liquid conductive is solution-state carbon nano-silver material or solution-state carbon nano-material.

11. A manufacturing method of an OLED display, comprising the following steps:
Step S1, providing a TFT substrate, forming a pixel defining layer on the TFT substrate;
arranging a plurality of through holes on the pixel defining layer; and defining a plurality of pixel areas on the TFT substrate according to the plurality of through holes;
Step S2, respectively printing liquid conductive material in the plurality of pixel areas of the TFT substrate, drying the liquid conductive material, and forming a conductive layer covering the pixel area;
Step S3, respectively printing liquid OLED luminescent material in the plurality of pixel areas in the TFT substrate, drying the liquid OLED luminescent material, and forming an OLED light emitting layer on the conductive layer;
Step S4, forming a cathode layer on the pixel defining layer and the OLED light emitting layer, and obtaining an OLED display;
wherein the TFT substrate comprises: a TFT array layer, a planarization layer covering on the TFT array layer, and a pixel electrode arranged on the planarization layer;
the plurality of through holes exposes the pixel electrode;
wherein material of the pixel electrode is transparent metal oxide;
wherein material of the liquid conductive is solution-state carbon nano-silver material or solution-state carbon nano-material.
